(19) United States
(12) Patent Application Publication
(10) Pub. No.: US 2011/0120555 A1
(43) Pub. Date: May 26, 2011

(54) PHOTOVOLTAIC DEVICES AND LIGHT SCATTERING SUPERSTRATES

(76) Inventors: Nicholas Francis Borrelli, Elmira, NY (US); Lisa Ann Lamberson, Painted Post, NY (US); Robert Michael Morena, Lindley, NY (US); Charlene Marie Smith, Corning, NY (US)

(21) Appl. No.: 12/950,294

(22) Filed: Nov. 19, 2010

Related U.S. Application Data
(60) Provisional application No. 61/263,493, filed on Nov. 23, 2009.

(51) Int. Cl. H01L 31/0232; B05D 5/06; H01L 31/18

(52) U.S. Cl. 136/259; 427/162; 438/64; 257/E31.124

(57) ABSTRACT

Photovoltaic devices having light scattering articles having a smooth surface are described herein. Glass frits on glass superstrates can provide planar surfaces for subsequent layer deposition such as TCO layers and yet provide light scattering functions within, for example, silicon tandem photovoltaic devices. Methods of making the light scattering articles with a planar surface include depositing unfilled or filled glass frits on planar or surface-textured superstrates and sintering of the glass frit. The compositions of the glass frits can be tailored to match, for example, the expansion properties and physical properties of the glass superstrates.

This application claims the benefit of priority to U.S. Provisional Application 61/263,493 filed on Nov. 23, 2010.

### BACKGROUND

1. Field

Embodiments relate to photovoltaic devices comprising light scattering superstrates and to methods of making light scattering superstrates, and more particularly to thin-film photovoltaic devices comprising light scattering superstrates having a smooth surface.

2. Technical Background

The efficiency of a thin film silicon-based photovoltaic cell determines to a large extent its economic viability. There are certain inherent limits to the theoretical efficiency of homo-junctions used in the photovoltaic cells, but the realized efficiency is considerably lower for a number of different reasons. One reason is the effective absorption of the solar spectrum. Simply increasing the thickness of the film especially the amorphous silicon is not the answer, because the range of the photo-electron is limited to 300 nm. The answer then is to somehow get more light into the silicon layer(s). This is not simple either, since the photovoltaic cell consists of a number of layers all of which can influence the light capture efficiency.

In a silicon tandem photovoltaic cell, there are several interfaces that can affect the light transmission. One idea proposed is to roughen the transparent electrode or transparent conductive oxide (TCO) film to allow the light to be scattered into the silicon at broad enough angles to allow light trapping by total internal reflection (TIR) in the silicon layer. This would effectively increase the absorption depth without increasing the thickness. The problem with this approach is that the amount of surface texture required to bring about the light trapping is very likely sufficient to increase the resistivity of the TCO and to introduce defects in the silicon film.

A typical tandem photovoltaic cell incorporating both amorphous and microcrystalline silicon has a substrate having a transparent electrode deposited thereon, a top cell of amorphous silicon, a bottom cell of microcrystalline silicon, and a back contact or counter electrode. Light is typically incident from the side of the deposition substrate such that the substrate becomes a superstrate in the cell configuration.

It would be advantageous to be able to scatter the light from the glass/TCO interface while keeping the TCO surface relatively flat. This could allow the subsequent texture of the TCO to be independently controlled. It would also be advantageous to have a superstrate with a smooth surface. The smooth surface could provide easier TCO deposition and/or quality.

### SUMMARY

One embodiment is a photovoltaic device comprising a superstrate, a planar glass frit layer disposed on a surface of the superstrate, and a conductive oxide layer adjacent to the glass frit layer.

Another embodiment is a method of making a light scattering article, the method comprises:
providing a superstrate;
applying a layer of glass frit to a surface of the superstrate; and
sintering the glass frit to form the scattering article, wherein a surface of the layer of glass frit is planar.

Another embodiment is a method of making a photovoltaic device, the method comprises:
providing a superstrate;
applying a layer of glass frit to a surface of the superstrate;
sintering the glass frit, wherein a surface of the layer of glass frit is planar;
applying a conductive material adjacent to the glass frit layer; and
applying a layer comprising silicon adjacent to the conductive material.

Additional features and advantages of the invention will be set forth in the detailed description which follows, and in part will be readily apparent to those skilled in the art from the description or recognized by practicing the invention as described in the written description and claims hereof, as well as the appended drawings.

It is to be understood that both the foregoing general description and the following detailed description are merely exemplary of the invention, and are intended to provide an overview or framework to understanding the nature and character of the invention as it is claimed.

The accompanying drawings are included to provide a further understanding of the invention, and are incorporated in and constitute a part of this specification. The drawings illustrate one or more embodiment(s) of the invention and together with the description serve to explain the principles and operation of the invention.

### BRIEF DESCRIPTION OF THE DRAWINGS

The invention can be understood from the following detailed description either alone or together with the accompanying drawings.

FIGS. 1A-1D are illustrations of features of an exemplary photovoltaic device.

FIG. 2 is an optical micrograph of an exemplary article.

FIG. 3 is a plot of white light angular scattering of exemplary articles.

FIG. 4A is a plot of total transmittance of an exemplary article.

FIG. 4B is a plot of diffuse transmittance of an exemplary article.

FIG. 5 is a plot of total and diffuse transmittance of exemplary articles.

FIG. 6 is a plot of total and diffuse transmittance of exemplary articles.

FIG. 7 is a plot of angular white light scattering of exemplary articles.

FIG. 8A is a plot of total transmittance of an exemplary article.

FIG. 8B is a plot of diffuse transmittance of an exemplary article.

FIG. 9A is an optical micrograph of an exemplary article.

FIG. 9B is an optical micrograph of an exemplary article.

FIG. 10A is a plot of roughness data of an exemplary article.

FIG. 10B is a plot of roughness data of an exemplary article.

FIGS. 11A-11C are graphs of angular intensity, cosine-corrected bidirectional transmission function (ccBTDF) versus angle at 400 nm, 600 nm, 800 nm, and 1000 nm wavelengths for exemplary articles comprising a 5%, 10%, or 15% ZnO filled glass frit.

FIGS. 12A-12C are graphs of angular intensity, cosine-corrected bidirectional transmission function (ccBTDF) versus angle at 400 nm, 600 nm, 800 nm, and 1000 nm wavelengths for exemplary articles comprising a 5%, 10%, or 15% spinel filled glass frit.

### DETAILED DESCRIPTION

Reference will now be made in detail to various embodiments of the invention, an example of which is illustrated in the accompanying drawings.

As used herein, the term “volumetric scattering” can be defined as the effect on paths of light created by inhomogeneities in the refractive index of the materials that the light travels through.

As used herein, the term “surface scattering” can be defined as the effect on paths of light created by interface roughness between layers in a photovoltaic cell.

As used herein, the terms “substrate” and “superstrate” can be used interchangeably to describe either a substrate or a superstrate depending on the configuration of the photovoltaic cell. For example, the substrate is a superstrate, if when assembled into a photovoltaic cell, it is on the light incident side of a photovoltaic cell. The superstrate can provide protection for the materials from impact and environmental degradation while allowing transmission of the appropriate wavelengths of the solar spectrum. Further, multiple photovoltaic cells can be arranged into a photovoltaic module.

As used herein, the term “adjacent” can be defined as being in close proximity. Adjacent structures may or may not be in physical contact with each other. Adjacent structures can have other layers and/or structures disposed between them.

As used herein, the term “planar” can be defined as having a substantially topographically flat surface.

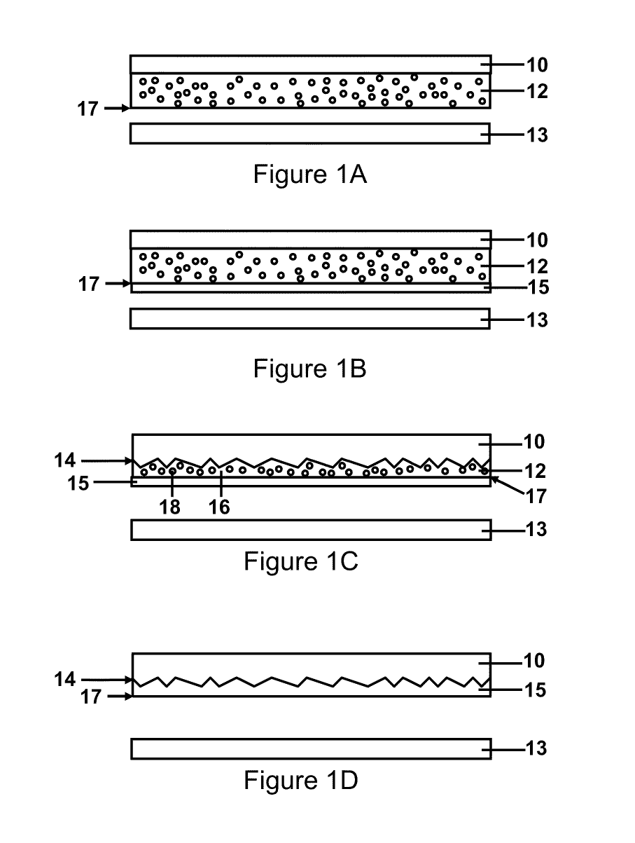

One embodiment, features of which are shown in FIGS. 1A-1D, is a photovoltaic device comprising a superstrate 10, and a planar glass frit layer 12 disposed on a surface of the superstrate, and a conductive oxide layer 13 adjacent to the glass frit layer.

In one embodiment, as shown in FIGS. 1A-1C, the planar glass frit layer is a filled glass frit. In embodiments comprising a planar filled glass frit and a planar superstrate, as shown in FIG. 1A, the filled glass frit provides the light scattering function while maintaining a planar surface 17. This planar surface can be advantageous for subsequent layer deposition. The planar surface can be described as a substantially topographically flat surface. The planar surface can also be described as being smooth. The planar glass frit, in one embodiment, has a surface roughness of 500 nm or less, for example, 400 nm or less, for example, 300 nm or less.

In one embodiment, the photovoltaic device comprises multiple filled glass frit layers disposed onto the superstrate.

The superstrate can be a glass superstrate comprising one or more layers. The layers can be the same material or different materials.

The superstrate, according to one embodiment, as shown in FIGS. 1C and 1D, comprises a glass layer having at least one textured surface 14. The textured surface, according to one embodiment, can be provided, for example, by the relative sizes of peaks and valleys found on the surface of a roughened glass substrate. The roughened surface can be made according to methods known by those skilled in the art, for example, by sand blasting, grinding, etching, or by a combination thereof the surface of the glass. In some embodiments, the textured surface can have a surface roughness of 1 micron or less.

In FIG. 1D, the glass frit layer 15 is an unfilled glass frit layer. In this embodiment, the textured surface 14 of the superstrate provides the light scattering function. In the embodiment shown in FIG. 1D, the planar surface 17 is maintained by the unfilled glass frit layer.

In FIGS. 1B and 1C, the glass frit layer 12 is a filled glass frit layer. In the embodiment shown in FIG. 1C, the textured surface 14 of the superstrate and the filled glass frit layer provide the light scattering function. In the embodiment shown in FIG. 1B, the filled glass frit layer provides the light scattering function. In the embodiments shown in FIGS. 1B and 1C, the planar surface 17 is maintained by the filled glass frit layer. In the embodiments shown in FIGS. 1B and 1C, the photovoltaic device comprises a layer of unfilled glass frit 15 on the filled glass frit layer. The unfilled glass frit layer can have a different refractive index than the filled glass frit layer thus providing additional light scattering.

In one embodiment, as shown in FIG. 1C, the filled glass frit layer 12 comprises a silicate glass matrix 16; and a material 18 entrained in the matrix having a different refractive index than the refractive index of the matrix. The material can be selected from particles, bodies, spheres, precipitates, crystals, spinel, dendrites, phase separated elements, phase separated compounds, air bubbles, air lines, voids, metal oxides, and combinations thereof. Exemplary metal oxides are aluminum oxide, magnesium oxide, zinc oxide, titanium oxide, magnesium aluminum oxide, and combinations thereof.

In one embodiment, the photovoltaic device comprises multiple unfilled glass frit layers disposed onto the filled glass frit layer(s).

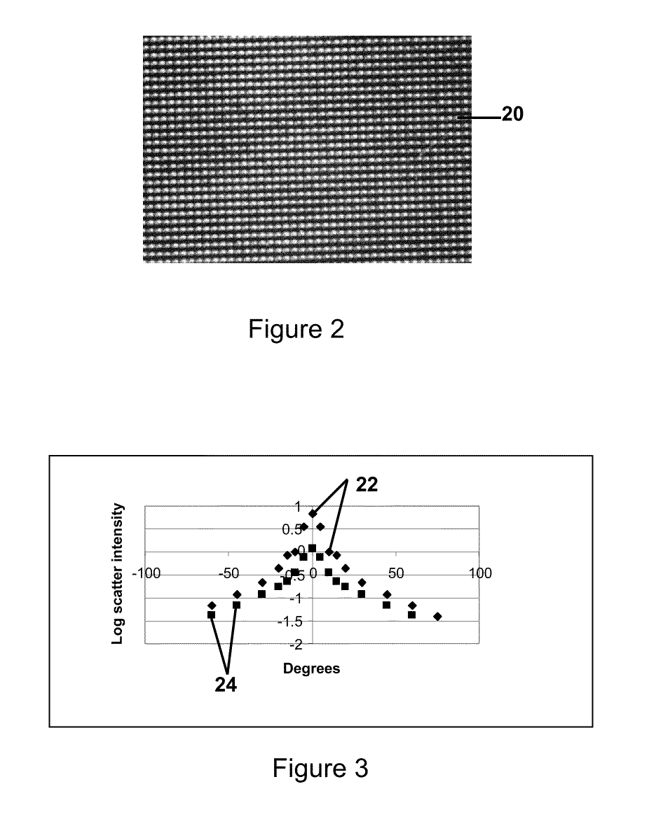

The glass frit layer, in one embodiment, is disposed in a pattern. In one embodiment, the glass frit is a filled glass frit and is disposed in a pattern. The pattern can be a random pattern or a nonrandom pattern, for example, a checker board pattern as shown in FIG. 2. In FIG. 2, a filled glass frit layer 20 is disposed in a pattern on a glass superstrate. An unfilled glass frit layer, in this example, is disposed on the patterned filled frit layer.

A transparent conductive oxide, in one embodiment, is adjacent to the filled glass frit. The transparent conductive oxide can be a textured TCO.

In one embodiment, the filled glass frit layer is planar. In another embodiment, the combination of the superstrate and the filled glass frit layer are planar. In another embodiment, the combination of the superstrate, the filled glass frit layer, and the unfilled glass frit layer are planar.

Another embodiment is a method of making a light scattering article, the method comprises:
providing a superstrate;
applying a layer of glass frit to a surface of the superstrate; and
sintering the glass frit to form the light scattering article, wherein a surface of the layer of glass frit is planar.

Another embodiment is a method of making a photovoltaic device, the method comprises:
providing a superstrate;
applying a layer of glass frit to a surface of the superstrate;
sintering the glass frit, wherein a surface of the glass frit is planar;
applying a conductive material adjacent to the glass frit layer; and
applying a layer comprising silicon adjacent to the conductive material.

The superstrate, in one embodiment, comprises a glass layer having at least one textured surface.

In one embodiment, the glass frit is a filled glass frit. Applying the layer of filled glass frit, according to one embodiment, comprises applying the layer in a pattern.

In one embodiment, applying the glass frit comprises spraying or screen printing the glass frit onto the superstrate. The glass frit, in this embodiment can be either a filled glass frit or an unfilled glass frit. Multiple filled or unfilled glass frit layers can be applied, for example, a first filled glass frit layer to the superstrate and subsequent filled glass frit layers to the first filled glass frit layer or a first unfilled glass frit layer to a textured surface of the superstrate and subsequent unfilled glass frit layers to the first unfilled glass frit layer.

In one embodiment, the method further comprises applying a conductive oxide adjacent to the filled glass frit layer.

In one embodiment, the method further comprises applying an unfilled glass frit layer adjacent to the filled glass frit layer. Multiple unfilled glass frit layers can be applied, for example, a first unfilled glass frit layer to the filled glass frit layer and subsequent unfilled glass frit layers to the first unfilled glass frit layer.

According to one embodiment, a slurry is prepared using amyl acetate with nitrocellulose as the binder. The slurry can be mixed, for example, slow roller-milled in glass jars to assure that the suspension is well mixed, and the filler material(s) well-dispersed. A hand-held air-brush can be used for spraying. In one embodiment, an unfilled glass frit layer is sprayed on top of the filled glass frit layer or layers for improved smoothness, and increased gloss.

In another embodiment, screen printing pastes can made using ethyl cellulose binder with texanol and various dispersant agents. The frit can be combined with the organic components and then mixed on a 3 roll mill. The pastes can be 3 roll milled. The pastes can be put in glass jars and slow rolled for several hours to remove any bubbles created in the paste during 3 roll milling. The final pastes, in one embodiment, are applied to a screen on an automated screen printing machine and a squeegee used to move the paste across the screen through a precise pattern onto the glass superstrate. The screen, in one embodiment, is a stainless steel mesh with a wire diameter of 28 μm or 18 μm with an open area between the wires of 51 μm square or 33 μm, respectively. The final thickness of the sintered filled glass frit, in one embodiment, is 20 microns or less, for example, 15 microns or less, for example, 10 microns to 15 microns.

A photovoltaic device, according to one embodiment, comprises, the article made according to the methods described herein.

### EXAMPLES

Glass frits were developed and designed to be expansion compatible with, for example, 1737™, JADE™, and EAGLE™ substrates. Exemplary glass frits are shown in Table 1 and Table 2. The exemplary glass frits shown in Table 2 are phase separable glass frits that upon thermal processing can be phase separated thus becoming filled glass frits. Exemplary filled glass frits are shown in Table 3. Frits and filled frits were applied to these three glass substrate surfaces by spray coating and/or screen printing. Screen printing is advantageous for applying the filled glass frit.

TABLE 1

| Composition | | | |
|---|---|---|---|
| (mole %) | 1 | 2 | 3 |
| SiO₂ | 78 | 78 | 65.1 |
| Al₂O₃ | | | 3.1 |
| B₂O₃ | 20.4 | 20.4 | 18.9 |
| Na₂O | 1.6 | | 3.3 |
| K₂O | | 1.6 | |
| Li₂O | | | 1.3 |
| CaO | | | 1.0 |
| F | | | 7.2 |

TABLE 2

| | Composition (mole %) | | | | | | | | | | | |
|---|---|---|---|---|---|---|---|---|---|---|---|---|
| | 4 | 5 | 6 | 7 | 8 | 9 | 10 | 11 | 12 | 13 | 14 | 15 |
| SiO₂ | 75.0 | 71.2 | 67.3 | 70.2 | 70.2 | 62.2 | 59.9 | 63.3 | 52.9 | 61.7 | 62.5 | 62.5 |
| B₂O₃ | 22.7 | 21.5 | 20.4 | 20.4 | 20.4 | 15.2 | 15.2 | 18.8 | 18.9 | 18.9 | 18.9 | 18.9 |
| Li₂O | 2.3 | 7.3 | 12.3 | 3.7 | 3.7 | 1.3 | 1.3 | 1.3 | 1.3 | 1.3 | 1.3 | 1.3 |
| Al₂O₃ | 0 | 0 | 0 | 3.4 | 5.4 | 3.1 | 3.1 | 1.6 | 1.6 | 1.6 | 1.6 | 1.6 |
| Na₂O | 0 | 0 | 0 | 0 | 0 | 3.4 | 3.4 | 3.4 | 3.4 | 3.4 | 3.4 | 3.4 |
| CaO | 0 | 0 | 0 | 1.1 | 1.1 | 0 | 0 | 1.0 | 1.0 | 1.0 | 1.0 | 1.0 |
| F— | 0 | 0 | 0 | 1.3 | 1.3 | 7.8 | 7.7 | 7.5 | 7.5 | 7.5 | 7.5 | 7.5 |
| TiO₂ | 0 | 0 | 0 | 3.0 | 5.0 | 0 | 0 | 0 | 0 | 0 | 0 | 0 |
| BaO | 0 | 0 | 0 | 0 | 0 | 4.6 | 4.6 | 1.6 | 2.8 | 2.3 | 1.6 | 2.3 |
| Cs₂O | 0 | 0 | 0 | 0 | 0 | 2.3 | 4.6 | 0 | 0 | 0 | 0 | 0 |
| La₂O₃ | 0 | 0 | 0 | 0 | 0 | 0 | 0 | 1.6 | 2.8 | 2.3 | 2.3 | 1.6 |

TABLE 3

| | Filler | Loading | Glass | Loading | Firing temperature |
|---|---|---|---|---|---|
| | (particle | (wt %) of | (particle | (Wt %) | for both coatings |
| Composition | size μm) | filler | size μm) | of glass | (blend and overcoat) |
| 16 | TiO₂, 16 | 10 | Comp. 1, 10 | 90 | 800 C.-1 hr |
| 17 | MgAl₂O₄, 1.5 | 10 | Comp. 1, 10 | 90 | 800 C.-1 hr |
| 18 | TiO₂, 16 | 10 | Comp. 1, 40-50 | 90 | none |
| 19 | MgAl₂O₄, 1.5 | 10 | Comp. 1, 40-50 | 90 | none |
| 20 | MgAl₂O₄, 1.5 | 7.5 | Comp. 1, 10 | 92.5 | 800 C.-1 hr |
| 21 | MgAl₂O₄, 1.5 | 7.5 | Comp. 1, 40-50 | 92.5 | none |
| 22 | MgAl₂O₄, 1 | 10 | Comp. 1, 10 | 90 | 800 C.-1 hr |
| 23 | MgAl₂O₄, 1 | 7.5 | Comp. 1, 10 | 92.5 | Each at 800 C.-1 hr, |
| | | | | | 800 C.-4 hr, 825 C.-4 hr |
| 24 | MgAl₂O₄, | 5 | Comp. 1, 3.5 | 95 | 800 C.-4 hr |
| 25 | TiO₂, 16 | 5 | Comp. 1, 3.5 | 95 | 800 C.-4 hrs & |
| | | | | | 850 C.-1 hr for overcoat |
| 26 | MgAl₂O₄, 1 | 5 | Comp. 1, 3.5 | 95 | 800 C.-4 hrs & |
| | | | | | 850 C.-1 hr for overcoat |
| 27 | none | none | Comp. 1, 3.5 | 100 | 800-4 hr, 850-1 hr |
| 28 | MgAl₂O₄, 1 | 12.5 | Comp. 1, 3.5 | 87.5 | |
| 29 | MgAl₂O₄, 1 | 15 | Comp. 1, 3.5 | 85 | |
| 30 | TiO₂, 16 | 7.5 | Comp. 1, 3.5 | 92.5 | 850 C.-4 hr |
| 31 | TiO₂, 0.6 | 7.5 | Comp. 2, 3.5 | 92.5 | 820 C.-1 hr, 835 C.-1 hr |
| 32 | TiO₂, 0.6 | 10 | Comp. 2, 3.5 | 90 | 820 C.-1 hr, 835 C.-1 hr |
| 33 | TiO₂, 0.6 | 12 | Comp. 2, 3.5 | 88 | 820 C.-1 hr, 835 C.-1 hr |
| 34 | TiO₂, 0.6 | 15 | Comp. 2, 3.5 | 85 | 820 C.-1 hr |
| 35 | TiO₂, 0.6 | 17 | Comp. 2, 3.5 | 83 | 820 C.-1 hr |
| 36 | TiO₂ | 2.5 | Comp. 2 | 97.5 | 350 C.-1 hr, 780 C.-4 h |
| 37 | TiO₂ | 5 | Comp. 2 | 95 | 350 C.-1 hr, 780 C.-4 h |
| 38 | TiO₂ | 1.75 | Comp. 3 | 98.25 | 350 C.-1 hr, 780 C.-4 h |
| 39 | ZnO | 5 | Comp. 2 | 95 | 350 C.-1 hr, 780 C.-4 h |
| 40 | ZnO | 10 | Comp. 2 | 90 | 350 C.-1 hr, 780 C.-4 h |
| 41 | ZnO | 15 | Comp. 2 | 85 | 350 C.-1 hr, 780 C.-4 h |

For the screen printing process pastes were made using ethyl cellulose binder with texanol and various dispersant agents. The frit was combined with the organic components and then mixed on a 3 roll mill. After 3 roll milling the pastes were put in glass jars and slow rolled for several hours to remove any bubbles created in the paste during 3 roll milling. The final pastes were then applied to a screen on an automated screen printing machine and a squeegee was used to move the paste across the screen through a precise pattern onto the glass substrate. The screen was stainless steel mesh with a wire diameter of 28 μm or 18 μm with an open area between the wires of 51 μm square or 33 μm, respectively. The final thickness of the sintered frit was approximately 12 μm.

Angular scattering of white light was measured for an exemplary TiO₂ filled glass frit with and without an unfilled glass frit layer. An example of white light angular scattering behavior of a 5% TiO₂ filled frit coating on Eagle XG™ glass, composition 25 in Table 3, is shown by diamond shaped points 22 in FIG. 3. The data represented by the square shaped points 24 in FIG. 3 correspond to a sample that was subsequently over-coated with an unfilled glass frit layer.

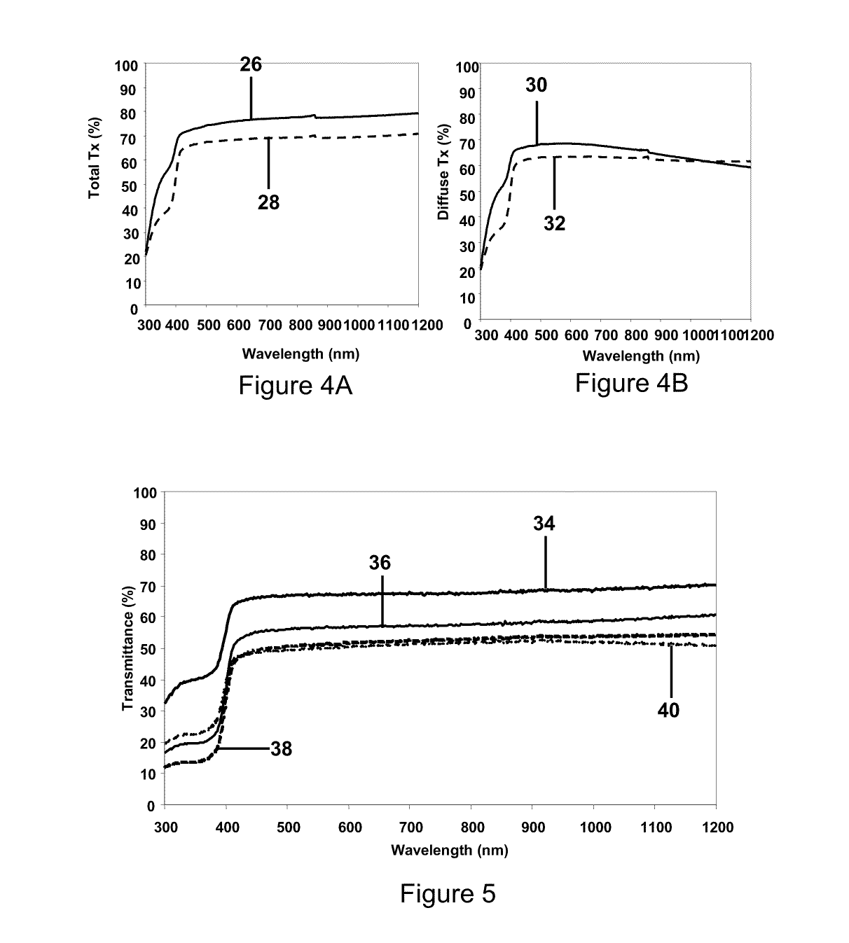

The total transmission and the diffuse transmission versus wavelength are shown in FIG. 4A and FIG. 4B, respectively, for an exemplary article made using composition in Table 3. Lines 28 and 32 correspond to the exemplary article with the filled glass frit layer; Lines 26 and 30 correspond to exemplary articles having the unfilled glass frit layer overcoat. The total transmission can be described as the light measured in the forward 180 degrees direction, while the diffuse measurement eliminates the specular portion of +/−12.5 degrees. The latter is thus a good estimate of the light scatter.

FIG. 5 is a plot of the total and diffuse transmission spectra for exemplary screen-printed articles. Glass sheets were coated with a layer of filled glass frit to form a light scattering article. The article was then over coated with an unfilled glass frit layer. Line 34 shows the total transmittance of an article made using composition 37 in Table 3. Line 36 shows the total transmittance of an article made using composition 36 in Table 3. Line 38 shows the diffuse transmittance of an article made using composition 36 in Table 3. Line 40 shows the diffuse transmittance of an article made using composition 37 in Table 3.

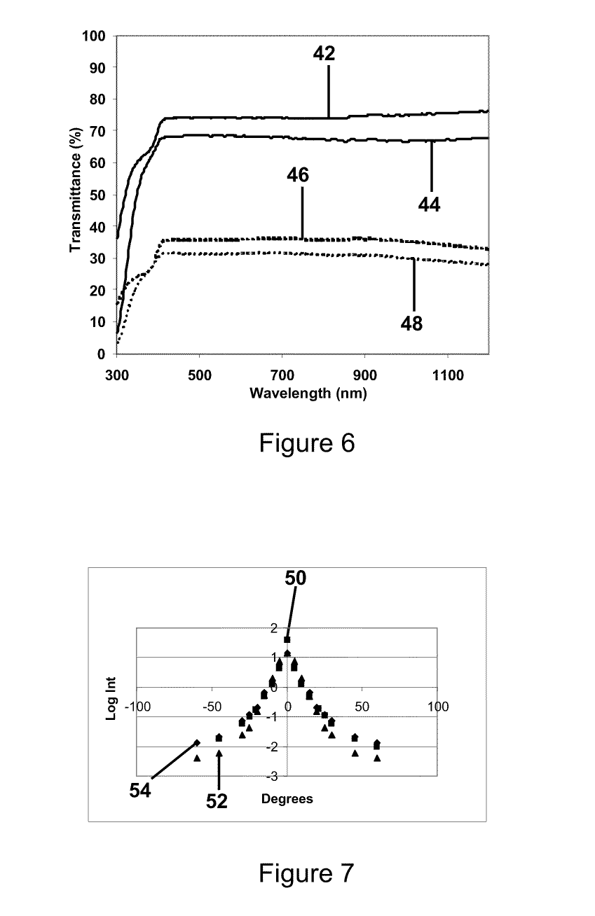

FIG. 6 is a plot of the total and diffuse transmission spectra for exemplary screen-printed articles. Glass sheets were coated with a layer of filled glass frit to form light scattering articles. The article was then over coated with an unfilled glass frit layer, in this example, the unfilled frit having composition 3 in Table 1. Line 42 shows the total transmittance of an article made using composition 38 in Table 3 on 0.7 mm thick Eagle™ glass. Line 44 shows the total transmittance of an article made using composition 38 in Table 3 on 3.5 mm Eagle™ glass. Line 46 shows the diffuse transmittance of an article made using composition 38 in Table 3 on 0.7 mm thick Eagle™ glass. Line 48 shows the diffuse transmittance of an article made using composition 38 in Table 3 on 3.5 mm Eagle™ glass.

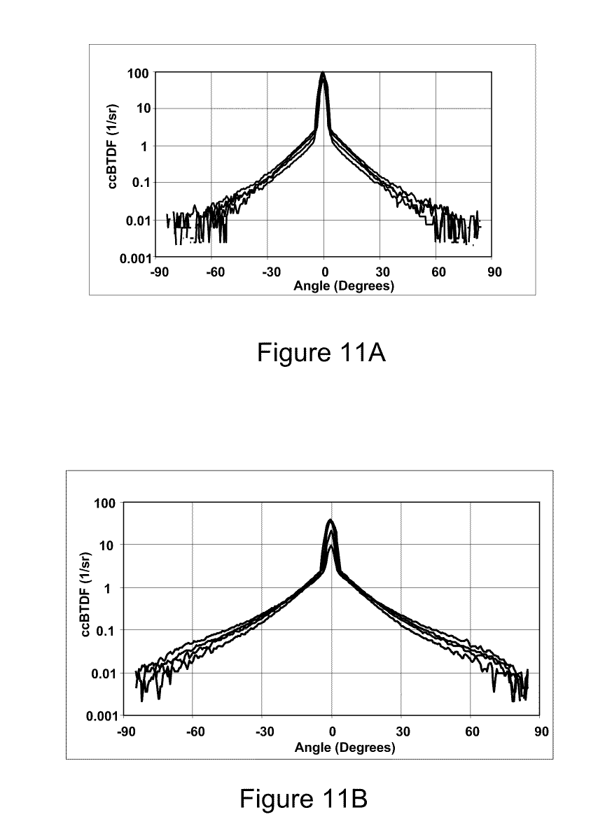

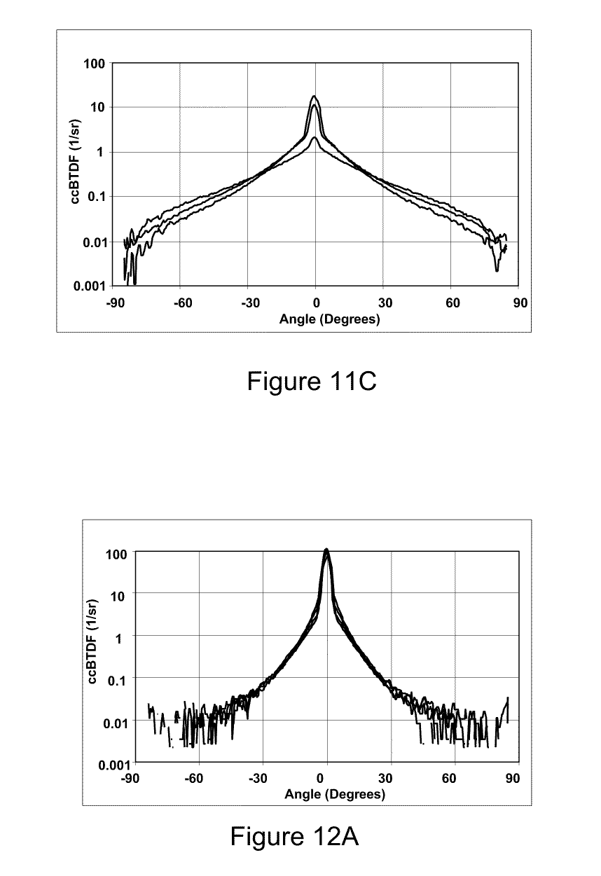

Additional filled glass frit articles were made by applying ZnO filled glass frits to glass superstrates. The filled glass frit had a 5%, 10%, or 15% ZnO filler (compositions 39-41 in Table 3). Graphs of angular intensity, cosine-corrected bidirectional transmission function (ccBTDF) versus angle at 400 nm, 600 nm, 800 nm, and 1000 nm wavelengths for articles comprising a 5%, 10%, or 15% ZnO filled glass frit are shown in FIGS. 11A-11C, respectively.

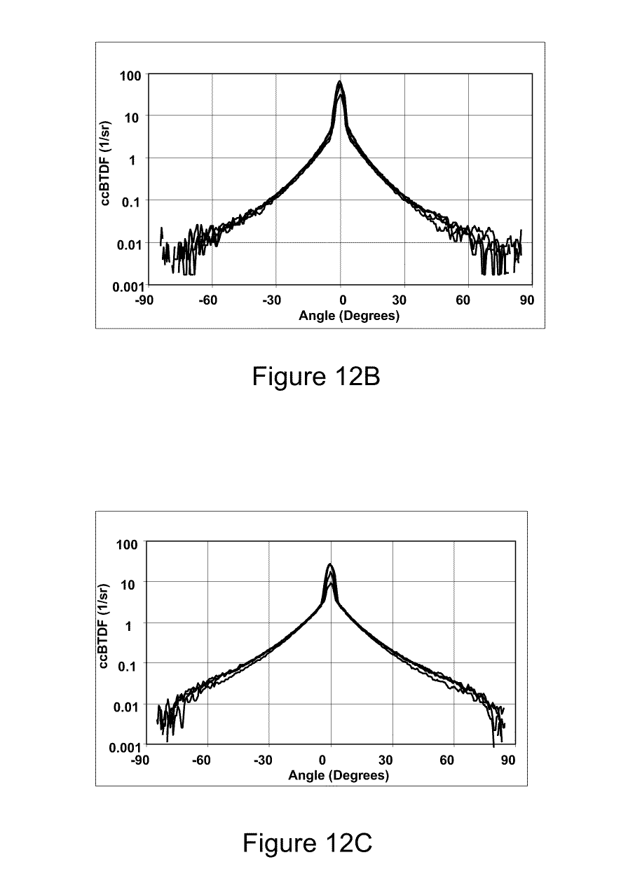

Additional filled glass frit articles were made by applying spinel filled glass frits to glass superstrates. The filled glass frit had a 5%, 10%, or 15% spinel filler. Graphs of angular intensity, cosine-corrected bidirectional transmission function (ccBTDF) versus angle at 400 nm, 600 nm, 800 nm, and 1000 nm wavelengths for articles comprising a 5%, 10%, or 15% spinel filled glass frit are shown in FIGS. 12A-12C, respectively. Articles comprising 15% spinel filled glass frit on a Soda-Lime superstrate were also made. This an example of a lower temperature filled glass frit on a lower temperature superstrate and compositionally comprises in mole percent 63.9 SiO₂, 7.3 Al₂O₃, 16.3 B₂O₃, 3.5 Li₂O, 3.0 Na₂O, 6.0 K₂O. The compositions of the glass frits can be tailored to match, for example, the expansion and physical properties of the glass superstrates.

In the examples discussed thus far, scattering was achieved by applying a filled glass frit to a polished glass surface to form a light scattering article. The use of a roughened glass surface was also investigated where angular scattering, total transmission and diffuse transmission for a lapped glass surface were measured. The use of a rough surface introduces the problems discussed above with respect to the electronic properties of the cell. Coating the lapped surface or the filled glass fritted surface described above with an overcoat of unfilled glass frit can then make the presenting surface smooth. Further, the overcoat removes the scattering layer anywhere from 20 to 80 μm from the glass surface. The effect of the overcoat on scattering behavior of filled frit coatings is shown in FIGS. 4A, 4B, 5, and 6.

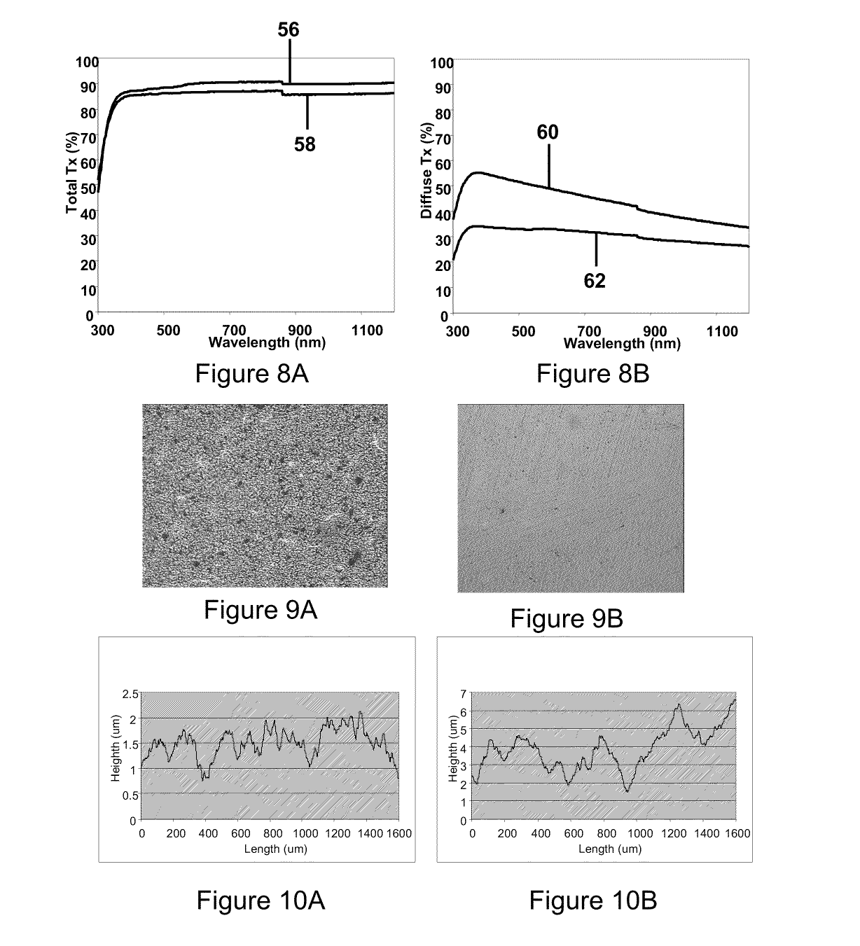

FIGS. 7, 8A, and 8B show the effect of the unfilled glass frit layer on scattering behavior for articles made using lapped and etched surfaces. Angular white light scatter of a ground and lapped surface, shown by points 54, as compared to etched in 6% HF for 75 minutes, shown by points 52, and unfilled glass frit, shown by points 50 is shown in FIG. 7.

FIG. 8A is a plot showing total transmission, and FIG. 8B is a plot showing diffuse transmission of exemplary articles made using ground and lapped surfaces, lines 58 and 60 are articles without an unfilled glass frit layer, and lines 56 and 62 are articles with an unfilled glass frit layer, in this example, composition 1 from Table 1.

To show the effect produced by the over-coating with an unfilled glass frit layer, optical reflection micrographs of an article made using a filled glass frit, in this example, composition 18 from Table 3, with an unfilled glass frit overcoat of composition 1 from Table 1 are shown in FIGS. 9A and 9B. FIG. 9A shows transmitted light and FIG. 9B shows reflected light.

In FIGS. 9A and 9B, the surface is qualitatively smoother, while below the surface the light scattering property persists. This is also seen in FIGS. 3 through 8 for white light angular scattering and the total and diffuse transmission curves where the data for the unfilled glass frit overcoated samples are indicated for comparison.

FIGS. 10A and 10B show quantitative roughness data of an article made using composition 22 in Table 3, with and without an unfilled frit overcoat, respectively. The article with the unfilled glass frit layer had a RMS roughness of 280 nm. The article without the unfilled glass frit layer had a RMS roughness of 1120 nm.

TABLE 4

| | Scan Size | | RMS |
|---|---|---|---|
| Sample | (microns) | Area | (nm) |
| Ground and | 20 | 1 | 418 |
| Lapped #7 Grit | 20 | 2 | 475 |
| | | Avg | 446.5 |
| Finish Ground | 20 | 1 | 604 |
| #332 Grit | 20 | 2 | 370 |
| | | Avg | 487.0 |
| Ground and | 20 | 1 | 765 |
| Lapped #32 Grit | 20 | 2 | 536 |
| | | Avg | 650.5 |
| 7403.1 ×12.5% | 20 | 1 | 6.3 |
| Spinel UT | 20 | 2 | 4.7 |
| overcoat 850 C. | | Avg | 5.5 |

Table 4 summarizes AFM results for ground and lapped surfaces, without an unfilled glass frit layer as compared to a filled glass frit layer with an unfilled glass frit overcoat.

The photovoltaic devices comprising filled glass frits may have one or more of the following advantages a smooth surface, light scattering is by volume scattering, the glass texture is decoupled from the TCO texture, the overall transmission can be maintained above 80%, and/or the diffuse scattering is limited to about 30% because of backscatter.

It will be apparent to those skilled in the art that various modifications and variations can be made to the present invention without departing from the spirit or scope of the invention. Thus, it is intended that the present invention cover the modifications and variations of this invention provided they come within the scope of the appended claims and their equivalents.

What is claimed is:

1. A photovoltaic device comprising:
a superstrate;
a planar glass frit layer disposed on a surface of the superstrate; and
a conductive oxide layer adjacent to the glass frit layer.

2. The device according to claim 1, wherein the planar glass frit layer is a filled glass frit layer.

3. The device according to claim 2, wherein the filled glass frit layer comprises a silicate glass matrix; and a material entrained in the matrix having a different refractive index than the refractive index of the matrix.

4. The device according to claim 3, wherein the material is selected from particles, bodies, spheres, precipitates, crystals, dendrites, phase separated elements, phase separated compounds, air inclusions, voids, metal oxides, or combinations thereof.

5. The device according to claim 4, wherein the metal oxide is selected from aluminum oxide, magnesium oxide, zinc oxide, titanium oxide, magnesium aluminum oxide, and combinations thereof.

6. The device according to claim 1, wherein the glass frit layer is disposed in a pattern.

7. The device according to claim 1, wherein the superstrate comprises a glass layer having at least one textured surface.

8. The device according to claim 7, wherein the textured surface has a surface roughness of 1 micron or less.

9. The device according to claim 1, wherein the conductive oxide layer is transparent.

10. The device according to claim 1, wherein the conductive oxide is textured.

11. The device according to claim 1, wherein the combination of the superstrate and the glass frit layer are planar.

12. A method of making a light scattering article, the method comprising:
providing a superstrate;
applying a layer of glass frit to a surface of the superstrate; and
sintering the glass frit to form the scattering article, wherein a surface of the layer of glass frit is planar.

13. The method according to claim 12, wherein the superstrate comprises a textured surface.

14. The method according to claim 12, wherein the glass frit is a filled glass frit.

15. The method according to claim 14, wherein applying the layer of filled glass frit comprises applying the layer in a pattern.

16. The method according to claim 12, further comprising applying a conductive material adjacent to the glass frit layer.

17. The method according to claim 12, wherein applying the glass frit comprises spraying or screen printing the glass frit onto the superstrate.

18. A photovoltaic device comprising the light scattering article made according to claim 12.

19. A method of making a photovoltaic device, the method comprising:
providing a superstrate;
applying a layer of glass frit to a surface of the superstrate;
sintering the glass frit, wherein a surface of the layer of glass frit is planar;
applying a conductive material adjacent to the glass frit layer; and
applying a layer comprising silicon adjacent to the conductive material.

20. The method according to claim 19, wherein the glass frit is a filled glass frit.
